(19) United States
(12) Patent Application Publication
(10) Pub. No.: US 2026/0329794 A1
(43) Pub. Date: Oct. 22, 2026

(54) IO EXPANSION ARCHITECTURE, IO SWITCHBOARD, AND PCIe DEVICE

(71) Applicant: Suzhou MetaBrain Intelligent Technology Co., Ltd., Suzhou, Jiangsu (CN)

(72) Inventors: Huijuan JIA, Suzhou, Jiangsu (CN); Tanlong CI, Suzhou, Jiangsu (CN); Tong XU, Suzhou, Jiangsu (CN)

(21) Appl. No.: 19/115,710

(22) PCT Filed: Aug. 13, 2024
(86) PCT No.: PCT/CN2024/111690

§ 371 Date: Mar. 26, 2025

(30) Foreign Application Priority Data
Oct. 10, 2023 (CN) 202311304011.4

(51) Int. Cl. G06F 13/40

(52) U.S. Cl. CPC G06F 13/4022; G06F 2213/0016; G06F 2213/0026

(57) ABSTRACT

Disclosed are an input/output (I/O) expansion architecture, an IO switchboard, and a peripheral component interface express (PCIe) device. The IO expansion architecture includes: at least one IO expansion unit, wherein the IO expansion unit includes an expansion baseboard; the expansion baseboard is provided with at least two PCIe Switch chips, a first preset quantity of internal connectors, and a second preset quantity of external connectors; one end of each internal connector is connected to any PCIe Switch chip on the expansion baseboard, and the other end of the internal connector is configured for interconnection between the PCIe Switch chips; and one end of each external connector is connected to any PCIe Switch chip on the expansion baseboard, and the other end of the external connector is configured for being connected to a PCIe device, to achieve the interconnection between the plurality of PCIe devices.

### CROSS-REFERENCE TO RELATED APPLICATIONS

This application claims priority to Chinese Patent Application No. 202311304011.4, entitled “IO EXPANSION ARCHITECTURE, IO SWITCHBOARD, AND PCIe DEVICE” and filed on Oct. 10, 2023, which is incorporated herein by reference in its entirety.

### FIELD

The present application relates to the technical field of computers, and in particular, to an input/output (IO) expansion architecture, an IO switchboard, and a peripheral component interface express (PCIe) device.

### BACKGROUND

With the rapid development of computer technologies, artificial intelligence (AI) models are becoming larger and larger, which has led to widespread attention to computing resource pooling and emergence of fusion architecture systems. In a fusion architecture system, a Host, IO, a graphic processing unit (GPU), a solid state drive (SSD), a Memory, and the like are decoupled into independent modules, becoming a specialized Host resource pool, IO resource pool, GPU resource pool, SSD resource pool, Memory resource pool, and the like, in order to achieve rapid expansion and upgrading of devices. The IO resource pool is an IO switchboard. In order to achieve fusion management on a large number of PCIe device resources, such as Host resources, GPU resources, SSD resources, and Memory resources, the IO switchboard plays a crucial role.

For the existing IO switchboard, a fixed number (such as 8) of PCIe slots are usually arranged on a switchboard baseboard. IO resources are exported from the PCIe slots by using a standard full/half height host bus adapter (HBA), and then the exported IO resources are used to perform inputting and outputting management on the PCIe device resources. However, this mode cannot effectively support exporting a large number of IO resources and cannot well meet construction requirements of complex topologies in the fusion architecture system. Furthermore, an HBA needed to be configured for protocol conversion, which is cumbersome in implementation and has high costs.

### SUMMARY

The present application provides an IO expansion architecture, an IO switchboard, and a PCIe device, to solve the problems in the related art that exporting of a large number of IO resources cannot be well supported, and construction requirements of complex topologies in a fusion architecture system cannot be well met.

The present application provides an IO expansion architecture, including:
at least one IO expansion unit, wherein the IO expansion unit includes an expansion baseboard; the expansion baseboard is provided with at least two PCIe Switch chips, a first preset quantity of internal connectors, and a second preset quantity of external connectors;
one end of each internal connector is connected to any PCIe Switch chip on the expansion baseboard, and the other end of the internal connector is configured for interconnection between the PCIe Switch chips; and one end of each external connector is connected to any PCIe Switch chip on the expansion baseboard, and the other end of the external connector is configured for being connected to a PCIe device, to achieve the interconnection between the plurality of PCIe devices.

The present application further provides an IO switchboard, including:
an identity document (ID) management unit, a control module, and the above IO extension architecture,
the ID management unit is configured to: acquire ID signals of all the internal connectors and all the external connectors in the IO expansion architecture, and transmit the ID signals to the control module; and
the control module is configured to manage all the PCIe Switch chips in the IO expansion architecture based on all the ID signals.

According to the IO switchboard provided by the present application, each of each internal connector and each external connector is connected with an ID definition chip; the ID definition chip is configured to perform ID definition on the corresponding internal connector or external connector;
the ID management unit is specifically configured to send an ID query instruction to each ID definition chip through the external connector or the internal connector;
the ID definition chip is further configured to: receive the ID query instruction, and feedback, based on the ID query instruction, the ID signal to the corresponding internal connector or external connector;
in a case that the internal connector or the external connector has received the ID signal, the ID signal is fed back to the ID management unit; and
the ID management unit is respectively connected to each external connector, each internal connector, and the control module.

According to the IO switchboard provided by the present application, the control module includes:
a multiplexer, configured to receive the ID signals transmitted by the ID management unit;
a logic control unit, configured to: monitor operating states of a baseboard management controller and all task management units; determine one of the baseboard management controller and all the task management units to be a target management unit based on the operating states, as well as task management priorities respectively corresponding to the baseboard management controller and the task management units; generate a target management unit instruction based on the determined target management unit; and send the target management unit instruction to the multiplexer,
wherein the multiplexer is further configured to: determine the target management unit based on the target management unit instruction, and send the ID signals to the target management unit; and
the baseboard management controller and at least one task management unit, wherein the baseboard management controller and each task management unit are both configured to: perform PCIe topology identification based on the ID signals in a case that the ID signals have been received, to obtain a PCIe interconnection topology; and manage all the PCIe Switch chips based on the PCIe interconnection topology;
the ID management unit is connected to the multiplexer; and the multiplexer is respectively connected to the logic control unit, the baseboard management controller, and all the task management units.

According to the IO switchboard provided by the present application, the at least one task management unit includes: a first task management unit and a second task management unit;
the logic control unit is specifically configured to: determine the first task management unit to be the target management unit when the first task management unit is in a normal operating state; determine the second task management unit to be the target management unit when the first task management unit is in an abnormal operating state and the second task management unit is in a normal operating state; determine the baseboard management controller to be the target management unit when both the first task management unit and the second task management unit are in abnormal operating states and the baseboard management controller is in a normal operating state.

According to the IO switchboard provided by the present application, both the baseboard management controller and each task management unit are specifically configured to send corresponding configuration information to each PCIe Switch chip in a case that the PCIe interconnection topology has been identified; the configuration information includes type information of all connection interfaces of the PCIe Switch chip; the connection interfaces include an interface configured to be connected to each internal connector or each external connector; the type information includes: uplink interface information, downlink interface information, and internal interconnect interface information; the uplink interface information means that the corresponding connection interface is an uplink interface; the uplink interface is configured to transmit a PCIe signal to a PCIe device connected uplink; the downlink interface information means that the corresponding connection interface is a downlink interface; the downlink interface is configured to transmit the PCIe signal to a PCIe device connected downlink; the interconnect interface information means that the corresponding connection interface is an internal interconnect interface; the internal interconnect interface is configured to transmit the PCIe signal to the remaining PCIe Switch chips interconnected with the current PCIe Switch chip; the PCIe device connected to uplink is a host, and the PCIe device connected to downlink is a graphics processing unit, a solid state drive, or a memory; and
the PCIe Switch chip is configured to configure all the connection interfaces of the PCIe Switch chip based on the received configuration information.

According to the IO switchboard provided by the present application, each PCIe Switch chip is configured to: obtain a target device type corresponding to the PCIe signal in a case of receiving the PCIe signal sent by the PCIe device; determine at least one target interface corresponding to the target device type from all the connection interfaces of the current PCIe Switch chip based on the target device type, and determine a PCIe device connected to the target interface to be a target PCIe device; send a state query instruction to the target PCIe device through the target interface; receive a task processing state fed back by each target PCIe device, wherein the task processing state is fed back by the target PCIe device based on the state query instruction; and send the PCIe signal to any target PCIe device with the task processing state being a free state.

According to the IO switchboard provided by the present application, each PCIe Switch chip is specifically configured to: transmit the PCIe signals to a preset message queue in a case that the task processing states fed back by all the target PCIe devices are operating states; and transmit, based on the message queue in a case that any target PCIe device is in the free state, the PCIe signals to the target PCIe device in the free state.

According to the IO switchboard provided by the present application, the IO switchboard further includes: a network management unit, wherein the network management unit is respectively connected to the baseboard management controller, the task management units, and the IO expansion unit, to achieve pairwise communication between the baseboard management controller, the IO expansion unit, and all the task management units.

According to the IO switchboard provided by the present application, the IO switchboard further includes: a heat dissipation unit, configured to perform heat dissipation on the IO switchboard.

According to the IO switchboard provided by the present application, the IO switchboard further includes: a power rail unit, wherein an input end of the power rail unit is configured to be connected to a power supply unit; and an output terminal of the power rail unit is respectively connected to the IO expansion unit, the ID management unit, the baseboard management controller, and the task management units, to supply power to the IO expansion unit, the ID management unit, the baseboard management controller, and the task management units.

According to the IO switchboard provided by the present application, the logic control unit is further configured to send a power on/off signal to the power rail unit, to control the power rail unit to start to supply or stop supplying power.

According to the IO switchboard provided by the present application, the first preset quantity of internal connectors are distributed on a first side of the corresponding expansion baseboard; the second preset quantity of external connectors are distributed on a second side of the corresponding expansion baseboard; and the first side and the second side are opposite sides.

The present application further provides a PCIe device, including: a switchboard connector, wherein the switchboard connector is configured to be connected to the external connectors in the above IO expansion architecture, or configured to be connected to the external connectors in any IO switchboard described above.

According to the PCIe device provided by the present application, the switchboard connector and the external connectors are connectors of the same type.

According to the PCIe device provided by the present application, the PCIe device is a host, a graphics processing unit, a solid state drive, or a memory.

The present application further provides a PCIe fusion architecture system, including:
any IO switchboard described above, and a plurality of the PCIe devices described above, wherein the plurality of PCIe devices are respectively connected to the corresponding external connectors.

The present application further provides a PCIe signal fusion management method based on the PCIe fusion architecture system described above, including:
receiving PCIe signals sent by PCIe devices;
obtaining a target device type corresponding to the PCIe signals;
determining at least one target interface corresponding to the target device type from all connection interfaces of a current PCIe Switch chip based on the target device type, and determining a PCIe device connected to the target interface to be a target PCIe device;
sending a state query instruction to the target PCIe device through the target interface;
receiving a task processing state fed back by each target PCIe device, wherein the task processing state information is fed back by the target PCIe device based on the state query instruction; and
sending the PCIe signal to any target PCIe device with the task processing state being a free state.

The present application further provides an electronic device, including a memory, a processor a computer program stored on the memory and runnable on the processor, wherein the processor implements any PCIe signal fusion management method described above.

The present application further provides a non-transient computer-readable storage medium, having a computer program stored therein, wherein the computer program, when run by a processor, implements any PCIe signal fusion management method described above.

The present application has the beneficial effects: According to the IO expansion architecture, the IO switchboard, and the PCIe device, by the arrangement of at least one IO expansion unit, the IO expansion unit includes an expansion baseboard; the expansion baseboard is provided with at least two PCIe Switch chips, a first preset quantity of internal connectors, and a second preset quantity of external connectors; one end of each internal connector is connected to any PCIe Switch chip on the expansion baseboard, and the other end of the internal connector is configured for interconnection between the PCIe Switch chips; and one end of each external connector is connected to any PCIe Switch chip on the expansion baseboard, and the other end of the external connector is configured for being connected to a PCIe device, to achieve the interconnection between the plurality of PCIe devices. The IO expansion architecture in the present application can well support exporting of a large number of or sufficient IO resources and can well meet construction requirements of complex topologies in a fusion architecture system, whereby the flexibility is high, and a possibility of project implementation is provided for construction of the complex topologies in the fusion architecture system.

### BRIEF DESCRIPTION OF THE DRAWINGS

To describe the technical solutions in the present application or in the related art more clearly, the following briefly introduces the accompanying drawings for describing the embodiments or the related art. Apparently, the accompanying drawings in the following description show some embodiments of the present application, and a person of ordinary skill in the art may still derive other drawings from the accompanying drawings without creative efforts.

FIG. 1 is a schematic structural diagram of an embodiment of an IO expansion architecture according to the present application;

FIG. 2 is a schematic structural diagram of an embodiment of an IO switchboard according to the present application;

FIG. 3 is a schematic structural diagram of another embodiment of an IO switchboard according to the present application;

FIG. 4 is a schematic structural diagram of an embodiment of a PCIe interconnection topology in a PCIe fusion architecture system according to the present application;

FIG. 5 is a flowchart of an embodiment of a PCIe signal fusion management method according to an embodiment of this application; and

FIG. 6 is a schematic structural diagram of an electronic device according to the present application.

### REFERENCE NUMERALS

110: expansion baseboard; 120: PCIe Switch chip; 130: internal connector; 140: external connector; 210: ID management unit; 220: control module; 221: multiplexer; 222: logic control unit; 223: first task management unit; 224: second task management unit; 225: baseboard management controller; 310: network management unit; 320: heat dissipation unit; 330: power rail unit; 340: power supply unit (PSU); and 350: HVDC power supply unit.

### DETAILED DESCRIPTION

In order to make the objectives, technical solutions, and advantages of the present application clearer, the technical solutions in the present application are clearly and achievely described below with reference to the accompanying drawings in the embodiments of the present application. Apparently, the described embodiments are merely some rather than all of the embodiments of the present application. All other embodiments obtained by a person of ordinary skill in the art based on the embodiments of the present application without making creative efforts shall fall within the protection scope of the present application.

An IO expansion architecture, an IO switchboard, and a PCIe device provided by the present application will be described below in combination with FIG. 1 to FIG. 6 according to embodiments.

Referring to FIG. 1, an IO expansion architecture provided by this embodiment includes:
at least one IO expansion unit, wherein the IO expansion unit includes an expansion baseboard 110; the expansion baseboard is provided with at least two PCIe Switch chips (which is simply denoted as SW in FIG. 1), a first preset quantity of internal connectors 130, and a second preset quantity of external connectors 140.

One end of each internal connector 130 is connected to any one of the PCIe Switch chips 120 on the expansion baseboard 110, and the other end of the internal connector 130 is configured for interconnection between the PCIe Switch chips 120. One end of each external connector 140 is connected to any PCIe Switch chip 120 on the expansion baseboard 110, and the other end of the external connector 140 is configured for being connected to a PCIe device, to achieve the interconnection between the plurality of PCIe devices.

Specifically, a quantity of the IO expansion units may be set according to an actual situation, such as 1, 2, 3, or 4. PCIe uses a point to point working mode. In the above embodiment, the PCIe Switch chips 120 are used to expand PCIe resources, which facilitates communication between the plurality of PCIe devices.

Further, by arranging the at least two PCIe Switch chips 120 on the expansion baseboard 110, PCIe resources can be expanded as many as possible. By arranging the first preset quantity of internal connectors 130, interconnection between the PCIe Switch chips 120 in the IO expansion architecture can be well achieved. By arranging the second preset quantity of external connectors 140, the plurality of PCIe devices can be effectively connected, thereby achieving construction of a PCIe interconnection topology.

It should be noted that the first preset quantity can be determined according to the quantity of the PCIe Switch chips 120 in the IO expansion architecture. For example, if there are totally four IO expansion units in the IO expansion architecture, each IO expansion unit includes two PCIe Switch chips 120, whereby there are totally eight PCIe Switch chips 120. In order to achieve interconnection between the eight PCIe Switch chips 120, 32 internal connectors 130 are required to achieve the interconnection between the eight PCIe Switch chips 120. Each PCIe Switch chip 120 corresponds to four internal connectors 130. Considering that a server (where the IO expansion architecture is located) usually has a standard size limitation. Many experiments show that an optimal value of the first preset quantity is 8, which means that each expansion baseboard 110 is provided with eight internal connectors 130, and each PCIe Switch chip 120 corresponds to four internal connectors 130. The above optimal value of the first preset quantity is for reference only. In an actual implementation process, the first preset quantity may be set according to an actual situation.

In addition, the second preset quantity may also be set according to an actual situation, such as 8 and 10. Similarly, due to the standard definition or limitation on the size of the server, many experiments show that an optimal value of the second preset quantity is 10, which means that each expansion baseboard 110 is provided with ten external connectors 140. Each PCIe Switch chip 120 corresponds to five corresponding external connectors 140, whereby PCIe resources are expanded within a range of the standard size as many as possible, to connect PCIe devices as many as possible.

The IO expansion architecture in the above embodiment can well support exporting of a large number of or sufficient PCIe resources or IO resources and can well meet construction requirements of complex topologies in a fusion architecture system, whereby the flexibility is high, and a possibility of project implementation is provided for construction of the complex topologies in the fusion architecture system. The costs are low, and the implementability is high.

It should be noted that the internal connector 130 in the above embodiment may be a mini cool edge IO (MCIO) connector. The external connector 140 in the above embodiment may be a compact duplex fiber pluggable (CDFP, which is a high-density fiber optic connector) connector. By using the above MCIO connector as the internal connector 130 and the CDFP connector as the external connector 140, requirements for a high bandwidth and a high transmission rate of data transmission can be met.

It should be noted that the CDFP connector is not only configured to receive and send a PCIe signal (i.e. receiving a PCIe signal sent by a PCIe device connected to it and sending a PCIe signal to the PCIe device connected to it), but also configured to send a plurality of preset signals, to meet different needs. Specifically, the CDFP connector further sends a virtual pin port (VPP)_inter-integrated circuit (I2C) signal and an Alert signal to the corresponding PCIe Switch chip 120, and the VPP_I2C signal and the Alert signal are configured for hot swapping of a hard disk drive in a solid state drive (SSD) resource pool. It can be understood that the VPP I2C signal can be configured for hot swappable PCIe management. The Alert signal can be configured for hot swapping alerting. In addition, in order to achieve synchronization with the corresponding PCIe Switch chip 120, the CDFP connector further sends a PCIe clock signal to the corresponding PCIe Switch chip 120, to achieve clock synchronization. In addition, the CDFP connector further sends a management (Mngt)_I2C signal to one of a baseboard management controller (BMC) 225 and all task management units for device information exchange between a plurality of resource pools. Furthermore, the CDFP connector further sends a Power enable signal, a Box present (an IO expansion unit connected state) signal, and a PERST signal (global reset signal) to a logic control unit 222 in the control module 220 for identification, power on/off, and reset of an entire cabinet system. Moreover, the CDFP connector further sends a Cable_I2C signal to a preset identity document (ID) management unit to read CDFP cable information and perform encryption and decryption operations, as well as an IDI2C signal to identify a preset ID of the CDFP connector. By defining signal types sent by the CDFP connector as described above, compatibility with a Host resource pool, a GPU resource pool, an SSD resource pool, and a Memory resource pool can be achieved.

It should also be noted that the MCIO connector is a standard board edge connector for signal interconnection between the PCIe Switch chips 120. The signals sent by the MCIO connector, except the PCIe signals, further include an ID_I2C signal for different PCIe Switch chips 120 to identify the preset ID of the MCIO connector.

By constructing the above IO expansion architecture, exporting of a large number of or sufficient IO resources can be well achieved, and construction requirements of complex topologies in a fusion architecture system can be well met, whereby the flexibility is high, and a possibility of project implementation is provided for construction of the complex topologies in the fusion architecture system. Furthermore, by defining the sent signals of the CDFP connector in many ways, diverse functional requirements can be met.

Four IO expansion units are taken as an example in FIG. 1. Each IO expansion unit has an expansion baseboard 110, and the four expansion baseboards 110 are stacked in sequence. Each expansion baseboard 110 is provided with two PCIe Switch chips 120, eight internal connectors 130, and ten external connectors 140. By arranging the two PCIe Switch chips 120, the eight internal connectors 130, and the ten external connectors 140 on each expansion baseboard 110, sufficient IO resources can be exported, which helps to construct a fusion architecture. One end of each of every four internal connectors 130 is connected to a corresponding PCIe Switch chip 120 on the same expansion baseboard 110, and the other end is respectively connected to each internal connector 130 of another IO expansion unit. One end of each of every five external connectors 140 is connected to a corresponding PCIe Switch chip 120 on the same expansion baseboard 110, and the other end is configured to be connected to an external PCIe device, to achieve interconnection of the plurality of PCIe devices and form a PCIe interconnection topology. This achieves the construction of the IO extension architecture in the above embodiment. The IO expansion architecture in this example can support the exporting of 40 IO resources. This can meet the construction requirements of the complex topologies in the fusion architecture system. The implementation is convenient and the feasibility is high.

In some embodiments, the IO expansion unit is further configured to be connected to a preset ID management unit 210. Specifically, the internal connectors 130 and the external connectors 140 in the IO expansion unit are respectively configured to be connected to the ID management unit 210. The external connectors 140 in the IO expansion unit is configured to be connected to the PCIe devices to obtain the PCIe signals, and transmit the PCIe signals to the PCIe Switch chips 120.

In some embodiments, the external connectors 140 and the internal connectors 130 are further configured to send their ID signals to the ID management unit 210. The ID management unit 210 sends the ID signals to the preset control module 220. The control module 220 performs interconnect topology identification based on the ID signals to obtain a PCIe interconnection topology; and manage all the PCIe Switch chips 120 in the IO expansion architecture based on the PCIe interconnection topology.

In some embodiments, the ID signals received by the PCIe Switch chips 120 are sent by a target management unit in the control module 220, and the target management unit is one of the baseboard management controller 225 and all the task management units in the control module 220. A mode for determining the target management unit is as follows: The logic control unit 222 in the control module 220 monitors operating states of the baseboard management controller 225 and all the task management units; determine one of the baseboard management controller 225 and all the task management units to be the target management unit based on the operating states, as well as task management priorities respectively corresponding to the baseboard management controller 225 and the task management units.

In some embodiments, that the ID management unit 210 sends the ID signals to the preset control module 220 includes: The ID management unit 210 sends the ID signals to a preset multiplexer (MUX) 221 in the control module 220. The multiplexer 221 determines the target management unit based on a target management unit control instruction sent by the logic control unit 222, and sends all the received PCIe signals to the target management unit.

According to the IO expansion architecture in the above embodiment, by arranging at least one IO expansion unit, the IO expansion unit includes an expansion baseboard 110; the expansion baseboard is provided with at least two PCIe Switch chips (which is simply denoted as SW in FIG. 1), a first preset number of internal connectors 130, and a second preset number of external connectors 140. One end of each internal connector 130 is connected to any one of the PCIe Switch chips 120 on the expansion baseboard 110, and the other end of the internal connector 130 is configured for interconnection between the PCIe Switch chips 120. In addition, one end of each external connector 140 is connected to any PCIe Switch chip 120 on the expansion baseboard 110, and the other end of the external connector 140 is configured for being connected to a PCIe device, to achieve the interconnection between the plurality of PCIe devices. Exporting of a large number of or sufficient IO resources can be well supported, and construction requirements of complex topologies in a fusion architecture system can be well met, whereby the flexibility is high, and a possibility of project implementation is provided for construction of the complex topologies in the fusion architecture system. The costs are low.

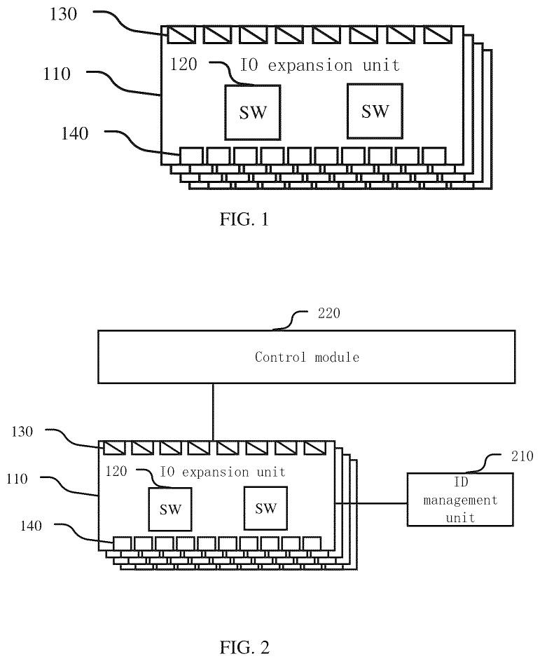

Referring to FIG. 2, this embodiment further provides an IO switchboard, including:
an ID management unit 210, a control module 220, and the above IO extension architecture.

The ID management unit 210 is configured to: acquire ID signals of all the internal connectors 130 and all the external connectors 140 in the IO expansion architecture, and transmit the ID signals to the control module 220.

The control module 220 is configured to manage all the PCIe Switch chips 120 in the IO expansion architecture based on all the ID signals. The IO switchboard in this embodiment has good IO resource expansion and share capability, has enough system robustness and flexibility, and can maintain IO exchange between the plurality of PCIe devices in an entire cabinet. Construction requirements of complex topologies in a fusion architecture system can be well met, whereby a possibility of project implementation is provided for construction of the complex topologies in the fusion architecture system, and the costs are high.

Specifically, by arranging the ID management unit 210 in the IO switchboard, acquisition of the ID signals for all the internal connectors 130 and all the external connectors 140 in the IO expansion architecture can be facilitated, and the acquired ID signals are sent to the control module 220, whereby the control module 220 performs PCIe interconnection topology identification. By arranging the control module 220 in the IO switchboard, management on all the PCIe Switch chips 120 can be facilitated. The IO switchboard in this embodiment can support exporting of a large number of or sufficient IO resources and can well meet construction requirements of complex topologies in a fusion architecture system, whereby the flexibility is high, and a possibility of project implementation is provided for construction of the complex topologies in the fusion architecture system. The costs are low; the implementability is high; and the automation degree is large.

In some embodiments, each of each internal connector 130 and each external connector 140 is connected with an ID definition chip. The ID definition chip is configured to perform ID definition on the corresponding internal connector 130 or external connector 140.

The ID management unit is specifically configured to send an ID query instruction to each ID definition chip through the external connector 140 or the internal connector 130.

The ID definition chip is further configured to: receive the ID query instruction, and feedback, based on the ID query instruction, the ID signal to the corresponding internal connector 130 or external connector 140.

In a case that the internal connector 130 or the external connector 140 has received the ID signal, the ID signal is fed back to the ID management unit 210.

The ID management unit 210 is respectively connected to each external connector 140, each internal connector 130, and the control module 220.

It should be noted that the ID management unit 210 is a core management unit in the IO switchboard, and is configured to: acquire the ID signals of all the internal connectors 130 or all the external connectors 140, and transmit the acquired ID signals to the target management unit. The target management unit is one of the baseboard management controller 225 and all the task management units in the control module 220.

It should also be noted that the internal connectors 130 and the external connectors 140 each have different ID signals from each other. In addition, in order to simplify an ID identification algorithm, each ID definition chip has the same I2C address and is in an identical I2C channel. That is, in the process of acquiring the ID signals by the ID management unit 210, an access address does not need to be switched for multiple times, which accelerates the identification speed, reduces the program complexity, has high implementability, low costs, and high identification efficiency.

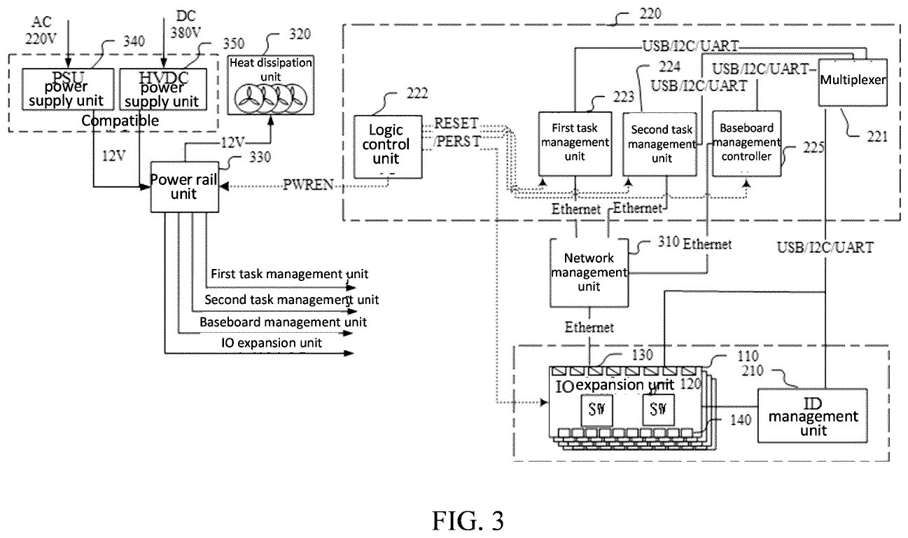

Referring to FIG. 3, in some embodiments, the control module 220 includes:
a multiplexer 221, configured to receive the ID signals transmitted by the ID management unit 210;
a logic control unit 222, configured to: monitor operating states of a baseboard management controller 225 and all task management units; determine one of the baseboard management controller 225 and all the task management units to be a target management unit based on the operating states, as well as task management priorities respectively corresponding to the baseboard management controller 225 and the task management units; generate a target management unit instruction based on the determined target management unit; and send the target management unit instruction to the multiplexer 221,
wherein the multiplexer 221 is further configured to: determine the target management unit based on the target management unit instruction, and send the ID signals to the target management unit; and
the baseboard management controller 225 and at least one task management unit, wherein the baseboard management controller 225 and each task management unit are both configured to: perform PCIe topology identification based on the ID signals in a case that the ID signals have been received, to obtain a PCIe interconnection topology; and manage all the PCIe Switch chips 120 based on the PCIe interconnection topology;
the ID management unit 210 is connected to the multiplexer 221; and the multiplexer 221 is respectively connected to the logic control unit 222, the baseboard management controller 225, and all the task management units. The ID management unit 210 and the multiplexer 221 can perform signal transmission or communication based on any one of a universal serial bus (USB), an I2C, and a universal asynchronous receiver/transmitter (UART). Similarly, signal transmission or communication can be achieved between the multiplexer 221 and the logic control unit 222, between the multiplexer 221 and the baseboard management controller 225, and between the multiplexer 221 and each task management unit based on any one of the USB, the I2C, and the UART. Based on different signal transmission types, corresponding communication protocols or modes can be used to meet different communication needs and support diverse functions.

Specifically, the multiplexer 221 receives the PCIe signals transmitted by the ID management unit 210 and sends the PCIe signals to the target management unit. The target management unit is determined by the logic control unit 222. That is, the logic control unit 222 monitors the operating states of the baseboard management controller 225 and all the task management units in real time; determines one of the baseboard management controller 225 and all the task management units to be the target management unit based on the operating states, as well as the task management priorities respectively corresponding to the baseboard management controller 225 and the task management units; generates the target management unit instruction based on the determined target management unit; and sends the target management unit instruction to the multiplexer 221. The multiplexer 221 determines the target management unit based on the target management unit instruction and sends the PCIe signals to the target management unit.

It should be noted that the baseboard management controller 225 and all the task management units in this embodiment can all achieve a function of managing all the PCIe Switch chips 120. In terms of this function, the baseboard management controller 225 and all the task management units constitute redundancy. The above embodiment can maximize the reliability of the IO switchboard and avoid unnecessary loss caused by a failure of a single signal allocation functional unit by determining one of the baseboard management controller 225 and all the task management units to be the target management unit.

It should be further noted that the priorities for managing all the PCIe Switch chips 120 mainly depend on the task management units. Namely, in a case that all the task management units fail, namely, in a case that all the management units are in abnormal operating states, the baseboard management controller 225 is determined to be the target management unit, and the baseboard management controller 225 serving as the target management unit is used to perform subsequent signal allocation and processing.

It should be noted that the baseboard management controller 225 in this embodiment not only has the function of managing all the PCIe Switch chips 120, but also needs to monitor basic information of the entire IO switchboard, such as acquiring information of a preset temperature sensor and the like in the IO switchboard, and making corresponding adjustments based on the basic information such as a temperature, such as controlling increase or decrease in a heat dissipation level of a preset heat dissipation unit 320 in the IO switchboard.

In addition, in order to achieve synchronization of information of the baseboard management controller 225 and all the task management units, and in order to reduce the difficulty of switching of a signal allocation function between the baseboard management controller 225 and all the task management units, the baseboard management controller 225 communicates pairwise with all the task management units to achieve real-time data exchange and backup, thus greatly improving the stability and reliability of the IO switchboard.

In some embodiments, the baseboard management controller 225 is a buckle that complies with a RunBMC specification (which is an open-source hardware specification), which is convenient for subsequent BMC chip upgrade. Moreover, the BMC supports a trans-flash (TF) card and related case management function interfaces.

In some embodiments, each task management unit is a central processing unit) management unit.

In some embodiments, the at least one task management unit includes: a first task management unit 223 and a second task management unit 224, namely, a first CPU management unit and a second CPU management unit. By arranging the first CPU management unit and the second CPU management unit, redundancy of the task management unit is formed, which helps to improve the stability and reliability of the IO switchboard. In order to better achieve engineering, in some embodiments, both the first CPU management unit and the second CPU management unit are buckles that comply with the COM express specification, which is convenient for subsequent processor upgrade. Moreover, each task management unit supports IO resources such as a PCIe network card, a PCIe non-volatile memory express (NVMe) hard disk drive or a serial advanced technology attachment (SATA) hard disk drive, and a PCIe debugging interface (for the PCIe Switch chip 120).

It should be noted that the first task management unit 223, the second task management unit 224, and the baseboard management controller 225 are configured for system management on the IO switchboard, and they are redundant with each other. By the redundancy between them, stable operation of the IO switchboard can be well ensured.

In some embodiments, the logic control unit 222 is specifically configured to: determine the first task management unit 223 to be the target management unit when the first task management unit 223 is in a normal operating state; determine the second task management unit 224 to be the target management unit when the first task management unit 223 is in an abnormal operating state and the second task management unit 224 is in a normal operating state; determine the baseboard management controller 225 to be the target management unit when both the first task management unit 223 and the second task management unit 224 are in abnormal operating states and the baseboard management controller 225 is in a normal operating state. Namely, task management priorities in this embodiment are: first task management unit 223-second task management unit 224-baseboard management controller 225. By setting the above task management priorities and using the task management priorities, task switching is performed on the first task management unit 223, the second task management unit 224, and the baseboard management controller 225. Specifically, which unit or controller is responsible for processing tasks such as receiving the ID signals, performing PCIe interconnection topology identification, and managing all the PCIe Switch chips 120. This can effectively ensure the stability and reliability of IO switchboard, and the flexibility is high. The logic control unit 222 effectively achieves redundant switching, power on/off timing sequence, and reset logic control in the IO switchboard, and can precisely ensure operations of the IO switchboard.

It should be noted that when the first task management unit 223 is in the abnormal operating state and the second task management unit 224 is in the normal operating state, the second task management unit 224 is determined to be the target management unit. Meanwhile, it attempts to restart the first task management unit 223. If the restart is achieved, the multiplexer 221 to switch a control permission to the first task management unit 223, namely, the first task management unit 223 is determined to be the target management unit again. Similarly, when both the first task management unit 223 and the second task management unit 224 are in the abnormal operating states, and the baseboard management controller 225 is in the normal operating state, the baseboard management controller 225 is determined to be the target management unit. Meanwhile, it attempts to restart the first task management unit 223 and the second task management unit 224. In a case that the first task management unit 223 is restarted successfully, the first task management unit 223 is determined to be the target management unit. In a case that the second task management unit 224 is restarted successfully and the first task management unit 223 is not restarted successfully, the second task management unit 224 is determined to be the target management unit. Thus, it can better ensure stable operations of the IO switchboard.

In a specific implementation process, a quantity of task management units can be adjusted according to an actual situation, to meet different actual needs.

In some embodiments, both the baseboard management controller 225 and each task management unit are specifically configured to send corresponding configuration information to each PCIe Switch chip in a case that the PCIe interconnection topology has been identified; the configuration information includes type information of all connection interfaces of the PCIe Switch chip; the connection interfaces include an interface configured to be connected to each internal connector or each external connector; the type information includes: uplink interface information, downlink interface information, and internal interconnect interface information; the uplink interface information means that the corresponding connection interface is an uplink interface; the uplink interface is configured to transmit a PCIe signal to a PCIe device connected uplink; the downlink interface information means that the corresponding connection interface is a downlink interface; the downlink interface is configured to transmit the PCIe signal to a PCIe device connected downlink; the interconnect interface information means that the corresponding connection interface is an internal interconnect interface; the internal interconnect interface is configured to transmit the PCIe signal to the remaining PCIe Switch chips interconnected with the current PCIe Switch chip; the PCIe device connected to uplink is a host, and the PCIe device connected to downlink is a graphics processing unit, a solid state drive, or a memory; and
the PCIe Switch chip is configured to configure all the connection interfaces of the PCIe Switch chip based on the received configuration information.

Specifically, in a case that the baseboard management controller 225 is the target management unit, the baseboard management controller 225 receives the ID signals, and performs topology identification based on all the ID signals to obtain the PCIe interconnection topology. In a case that the PCIe interconnection topology has been identified, the baseboard management controller 225 sends corresponding configuration information to each PCIe Switch chip 120; the configuration information includes type information of all connection interfaces of the PCIe Switch chip 120; the connection interfaces include an interface configured to be connected to each internal connector or each external connector; the type information includes: uplink interface information, downlink interface information, and internal interconnect interface information; the uplink interface information means that the corresponding connection interface is an uplink interface; the uplink interface is configured to transmit a PCIe signal to a PCIe device connected uplink; the downlink interface information means that the corresponding connection interface is a downlink interface; the downlink interface is configured to transmit the PCIe signal to a PCIe device connected downlink; the interconnect interface information means that the corresponding connection interface is an internal interconnect interface; the internal interconnect interface is configured to transmit the PCIe signal to the remaining PCIe Switch chips interconnected with the current PCIe Switch chip 120; the PCIe device connected to uplink is a host, and the PCIe device connected to downlink is a graphics processing unit, a solid state drive, or a memory; and the PCIe Switch chip 120 is configured to configure all the connection interfaces of the PCIe Switch chip based on the received configuration information.

Specifically, in a case that each task management unit is the target management unit, the task management unit receives the ID signals, and performs topology identification based on all the ID signals to obtain the PCIe interconnection topology. In a case that the PCIe interconnection topology has been identified, the task management unit sends corresponding configuration information to each PCIe Switch chip 120; the configuration information includes type information of all connection interfaces of the PCIe Switch chip 120; the connection interfaces include an interface configured to be connected to each internal connector or each external connector; the type information includes: uplink interface information, downlink interface information, and internal interconnect interface information; the uplink interface information means that the corresponding connection interface is an uplink interface; the uplink interface is configured to transmit a PCIe signal to a PCIe device connected uplink; the downlink interface information means that the corresponding connection interface is a downlink interface; the downlink interface is configured to transmit the PCIe signal to a PCIe device connected downlink; the interconnect interface information means that the corresponding connection interface is an internal interconnect interface; the internal interconnect interface is configured to transmit the PCIe signal to the remaining PCIe Switch chips 120 interconnected with the current PCIe Switch chip; the PCIe device connected to uplink is a host, and the PCIe device connected to downlink is a graphics processing unit, a solid state drive, or a memory; and the PCIe Switch chip 120 is configured to configure all the connection interfaces of the PCIe Switch chip based on the received configuration information.

In some embodiments, each PCIe Switch chip 120 is configured to: obtain a target device type corresponding to the PCIe signal in a case of receiving the PCIe signal sent by the PCIe device; determine at least one target interface corresponding to the target device type from all the connection interfaces of the current PCIe Switch chip 120 based on the target device type, and determine a PCIe device connected to the target interface to be a target PCIe device; send a state query instruction to the target PCIe device through the target interface; receive a task processing state fed back by each target PCIe device, wherein the task processing state is fed back by the target PCIe device based on the state query instruction; and send the PCIe signal to any target PCIe device with the task processing state being a free state.

In some embodiments, each PCIe Switch chip 120 is specifically configured to: transmit the PCIe signals to a preset message queue in a case that the task processing states fed back by all the target PCIe devices are operating states; and transmit, based on the message queue in a case that any target PCIe device is in the free state, the PCIe signals to the target PCIe device in the free state.

Through the above mode, the PCIe signal transmission efficiency can be effectively improved, and the feasibility is high.

It should be noted that each type of target PCIe device corresponds to one message queue. For example, when the target PCIe devices are solid state drives and are all in operating states, the current PCIe signals are placed into the message queue corresponding to the solid state drive. Furthermore, task processing states of all the target PCIe devices (solid state drives) are monitored in real time. In a case that the task processing state of any target PCIe device is in the free state, the PCIe signals in the message queue are sent to the target PCIe device in the free state.

In some embodiments, when the baseboard management controller 225 and each task management unit are used as the target management units, exchange of the PCIe signals is achieved by managing and scheduling the PCIe Switch chips 120 in the IO expansion unit.

In some embodiments, the IO switchboard further includes: a network management unit 310. The network management unit 310 is respectively connected to the baseboard management controller 225, the task management units, and the IO expansion unit, to achieve pairwise communication between the baseboard management controller 225, the IO expansion unit, and all the task management units.

Specifically, the baseboard management controller 225, the IO expansion unit, and all the task management units pairwise communicate with each other through the network management unit 310, thus achieving Ethernet communication between them and completing real-time data exchange and data backup. This helps to increase a speed of switching a task between the baseboard management controller 225 and all the task management units (this task is a signal allocation or processing task), and also helps to improve the stability of the IO switchboard. Based on the network management unit 310 in the above embodiment, star interconnection between the baseboard management controller 225, the task management units, and the IO expansion unit can be achieved, and any two devices can access each other.

It should be noted that each PCIe Switch chip 120 of the IO expansion unit is provided with a network interface for network connection.

In some embodiments, the network management unit 310 is further externally connected with a plurality of network interfaces. The network interfaces can be configured to access any device of the baseboard management controller 225, the task management units, and the PCIe Switch chips 120. Each network interface can use a registered jack 45 (RJ45, which is a connector) network interface.

The baseboard management controller 225 and each task management unit both transmit the configuration information to the IO expansion unit through the network management unit 310.

In some embodiments, the IO switchboard further includes: a heat dissipation unit 320, configured to perform heat dissipation on the IO switchboard. Specifically, the heat dissipation unit 320 is composed of four dual-rotor fans, supporting clockwise and counterclockwise rotation, supporting a fan redundancy design, ensuring heat dissipation of the IO switchboard, and helping to improve the stability of the IO switchboard. It should be noted that a quantity of the dual-rotor fans can be adjusted according to an actual situation, to meet different scene requirements.

In some embodiments, the IO switchboard further includes: a power rail unit 330. An input end of the power rail unit 330 is configured to be connected to a power supply unit. An output terminal of the power rail unit 330 is respectively connected to the IO expansion unit, the ID management unit 210, the baseboard management controller 225, and the task management units, to supply power to the IO expansion unit, the ID management unit 210, the baseboard management controller 225, and the task management units. In some embodiments, the power rail unit 330 is further configured to supply power to the heat dissipation unit 320. Specifically, a 12V power supply can be used to supply power to the heat dissipation unit 320. By arranging the power rail unit 330, a power supplying need of multiple devices in the IO switchboard can be met.

In some embodiments, the power supply unit includes: a power supply unit (PSU, alternating current) power 340 and a high voltage direct current (HVDC) power supply unit 350. Due to the compatibility between the PSU 340 and HVDC power supply unit 350, various power supplying needs can be met. The PSU 340 is connected to an external alternating current (AC) power supply, and the HVDC power supply unit 350 is connected to an external direct current (DC) power supply. Due to the compatibility between the AC power supply and the DC power supply, the external power supply is converted into 12V for internal use of the IO switchboard, to meet different power supplying scenes. The above AC power supply can be 220V, or the like, and the DC power supply can be 380V, or the like.

In some embodiments, the logic control unit 222 is further configured to send a power on/off signal (PWREN) to the power rail unit 330, to control the power rail unit to start to supply or stop supplying power.

In some embodiments, the first preset quantity of internal connectors 130 are distributed on a first side of the corresponding expansion baseboard 110, and the second preset quantity of external connectors 140 are distributed on a second side of the corresponding expansion baseboard 110. The first side and the second side are opposite sides. By using the above mode to arrange the internal connectors 130 and the external connectors 140, the difficulty and complexity of wiring can be reduced.

According to the IO switchboard in the above embodiment, by using the highly flexible IO expansion architecture, exporting of a large number of or sufficient IO resources can be achieved, to connect uplink and downlink PCIe devices. Moreover, by using the multiplexer 221, the logic control unit 222, the first task management unit 223, and the second task management unit 224, the stability and reliability of operation of the IO switchboard can be well ensured, and the IO switchboard has low costs, high implementability, and high density, robustness, and flexibility. It has strong system robustness to maintain the stability of an IO switchboard system, which ensures IO data exchange between multiple devices in an entire cabinet. It has flexible expansion and is compatible with different power supplying modes and PCIe Switch interconnect topologies in different forms.

A PCIe device provided in the present application will be described below. The PCIe device described below can correspond to the IO switchboard described above.

This embodiment further provides a PCIe device, including: a switchboard connector. The switchboard connector is configured to be connected to the external connectors 140 in the above IO expansion architecture, or configured to be connected to the external connectors 140 in any IO switchboard described above. The PCIe device in this embodiment can achieve better interaction and intercommunication between different PCIe resources by connection to the external connectors 140 in the above IO expansion architecture, or by connection to the external connectors 140 in any IO switchboard described above, with high flexibility.

In some embodiments, the switchboard connector and the external connectors 140 are connectors of the same type. Specifically, the switchboard connector is a CDFP connector.

In some embodiments, the PCIe device is a host, a graphics processing unit (GPU), a solid state drive (SSD), or a memory.

A PCIe fusion architecture system provided in the present application will be described below. The PCIe fusion architecture system described below can correspond to the IO switchboard and the PCIe device described above.

This embodiment further provides a PCIe fusion architecture system, including:
any IO switchboard described above, and a plurality of the PCIe devices described above, wherein the plurality of PCIe devices are respectively connected to the corresponding external connectors 140. The PCIe fusion architecture system in this embodiment can well support exporting of a large number of or sufficient IO resources and can well meet construction requirements of complex topologies in the fusion architecture system, with high flexibility, high implementability, and low costs.

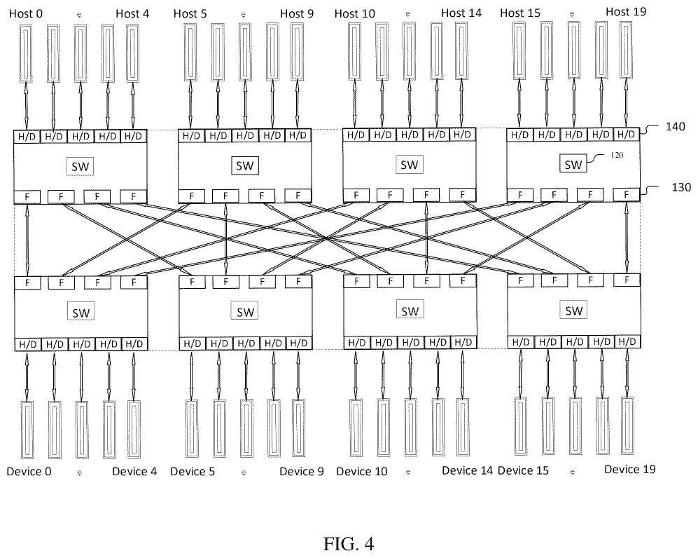

Referring to FIG. 4, eight PCIe Switch chips 120 are taken as an example. Each PCIe Switch chip 120 (referred to as SW in FIG. 4) are correspondingly connected to five external connectors 140 (referred to as H/D in FIG. 4) and four internal connectors 130 (referred to as F in FIG. 4). Each internal connector 130 is configured to be connected to each internal connector 130 of other PCIe Switch chips 120 to form interconnection between the PCIe Switch chips 120. Each external connector 140 is connected to a PCIe device. The PCIe device can be a host, a solid state drive, a graphics processing unit, or a memory. In FIG. 4, the eight PCIe Switch chips 120 are exemplarily divided into four upper PCIe Switch chips and four lower PCIe Switch chips. The external connectors 140 of the four upper PCIe Switch chips 120 are connected to hosts (such as Host0 . . . Host4, Host5 . . . Host9, Host10 . . . Host14, Host15 . . . Host19 in FIG. 4). Furthermore, the external connectors 140 of the four lower PCIe Switch chips 120 are connected solid state drives, graphics processing units, or memories (such as Device0 . . . Device4, Device 5 . . . Device9, Device10 . . . Device14, Device15 . . . Device19 in FIG. 4), that is, Device in FIG. 4 can be a solid state drive, a graphics processing unit, or a memory. The PCIe fusion architecture system is constructed using Host-IO switchboard-Device, which has high instantaneity and better meets the construction requirements of complex topologies. It can schedule and allocate various GPU resources, SSD resources, and Memory resources between different hosts. It should be noted that in a specific implementation process, other topology forms can also be configured for topology construction.

For example, six PCIe Switch chips 120 are taken as an example. Each PCIe Switch chip 120 is correspondingly connected to five external connectors 140 and three or fourth internal connectors 130. Each internal connector 130 is configured to be connected to each internal connector 130 of other PCIe Switch chips 120 to form interconnection between the PCIe Switch chips 120. Each external connector 140 is connected to a PCIe device. The PCIe device can be a host, a solid state drive, a graphics processing unit, or a memory. The six PCIe Switch chips 120 can be divided into three upper PCIe Switch chips and three lower PCIe Switch chips. The external connectors 140 of the three upper PCIe Switch chips 120 are connected to a host. Furthermore, the external connectors 140 of the three lower PCIe Switch chips 120 are connected to a solid state drive, a graphics processing unit, or a memory. Thus, a fusion architecture or a PCIe interconnection topology based on six PCIe Switch chips 120 can be constructed. Many GPU resources, SSD resources, and Memory resources are scheduled and allocated between different Hosts, to meet different fusion architecture construction requirements.

In addition, four PCIe Switch chips 120 are taken as an example. Correspondingly, every two PCIe Switch chips 120 are arranged on the same expansion baseboard 110. Each PCIe Switch chip 120 is correspondingly connected to five external connectors 140 and two, three, or four internal connectors 130. Each internal connector 130 is configured to be connected to each internal connector 130 of other PCIe Switch chips 120 to form interconnection between the PCIe Switch chips 120. Each external connector 140 is connected to a PCIe device. The PCIe device can be a host, a solid state drive, a graphics processing unit, or a memory. The four PCIe Switch chips 120 can be divided into two upper PCIe Switch chips and two lower PCIe Switch chips. The external connectors 140 of the two upper PCIe Switch chips 120 are connected to a host. Furthermore, the external connectors 140 of the two lower PCIe Switch chips 120 are connected to a solid state drive, a graphics processing unit, or a memory. Thus, a fusion architecture or a PCIe interconnection topology based on four PCIe Switch chips 120 can be constructed, with high flexibility.

In addition, two PCIe Switch chips 120 are taken as an example. Correspondingly, the two PCIe Switch chips 120 are arranged on the same expansion baseboard 110. Each PCIe Switch chip 120 is correspondingly connected to five external connectors 140 and one internal connector 130. Each PCIe Switch chip 120 is connected to the internal connectors 130 of other PCIe Switch chips 120 through its internal connector 130 to achieve interconnection between the two PCIe Switch chips 120. Each external connector 140 is connected to a PCIe device. The PCIe device can be a host, a solid state drive, a graphics processing unit, or a memory. The external connectors 140 of one PCIe Switch chip 120 are connected to a host. Furthermore, the external connectors 140 of the other PCIe Switch chip 120 are connected to a solid state drive, a graphics processing unit, or a memory. Thus, a fusion architecture or a PCIe interconnection topology based on two PCIe Switch chips 120 can be constructed, with high flexibility and low costs.

Eight, six, four, and two PCIe Switch chips 120 are respectively taken as examples above. It can be seen that the PCIe fusion architecture system in the above embodiment has high flexibility. In a specific implementation process, adaptive modifications can be made to the above PCIe interconnection topology according to an actual need, which will not be elaborated here.

It should be noted that the PCIe fusion architecture system in the above embodiment can well support exporting of a large number of or sufficient IO resources and can well meet construction requirements of complex topologies in a fusion architecture system, whereby the flexibility is high, and a possibility of project implementation is provided for construction of the complex topologies in the fusion architecture system. The PCIe fusion architecture system has high density, robustness, and flexibility, and can meet application needs of different scenes.

A PCIe signal fusion management method provided in the present application will be described below. The PCIe signal fusion management method described below can correspond to the PCIe fusion architecture system described above.

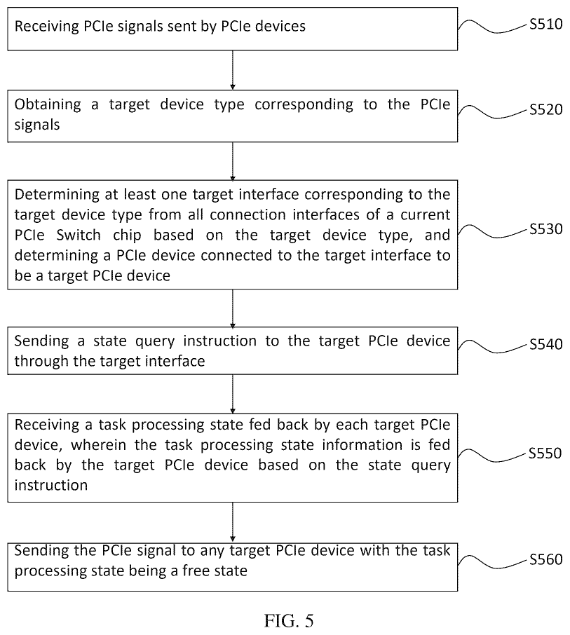

Referring to FIG. 5, this embodiment further provides a PCIe signal fusion management method based on the PCIe fusion architecture system described above, including:
S510: Receiving PCIe signals sent by PCIe devices.
S520: Obtaining a target device type corresponding to the PCIe signals.
S530: Determining at least one target interface corresponding to the target device type from all connection interfaces of a current PCIe Switch chip based on the target device type, and determining a PCIe device connected to the target interface to be a target PCIe device.
S540: Sending a state query instruction to the target PCIe device through the target interface.
S550: Receiving a task processing state fed back by each target PCIe device, wherein the task processing state information is fed back by the target PCIe device based on the state query instruction; and
S560: Sending the PCIe signal to any target PCIe device with the task processing state being a free state. The method can well improve the PCIe signal transmission efficiency in the PCIe fusion architecture system, with high flexibility, high implementability, and low costs.

In some embodiments, the PCIe signal fusion management method further includes: transmitting the PCIe signals to a preset message queue in a case that the task processing states fed back by all the target PCIe devices are operating states; and transmitting, based on the message queue in a case that any target PCIe device is in the free state, the PCIe signals to the target PCIe device in the free state.

It should be noted that the PCIe signal fusion management method in the above embodiment is performed based on the PCIe fusion architecture system in the above embodiment. The PCIe fusion architecture system can well support exporting of a large number of or sufficient IO resources can be well supported, and well meet construction requirements of complex topologies in a fusion architecture system, whereby the flexibility is high, and a possibility of project implementation is provided for construction of the complex topologies in the fusion architecture system. The PCIe fusion architecture system has low costs and high density, robustness, and flexibility.

In summary, according to the IO expansion architecture, the IO switchboard, and the PCIe device, by the arrangement of at least one IO expansion unit, the IO expansion unit includes an expansion baseboard; the expansion baseboard is provided with at least two PCIe Switch chips, a first preset quantity of internal connectors, and a second preset quantity of external connectors; one end of each internal connector is connected to any PCIe Switch chip on the expansion baseboard, and the other end of the internal connector is configured for interconnection between the PCIe Switch chips; and one end of each external connector is connected to any PCIe Switch chip on the expansion baseboard, and the other end of the external connector is configured for being connected to a PCIe device, to achieve the interconnection between the plurality of PCIe devices. Exporting of a large number of or sufficient IO resources can be well supported, and construction requirements of complex topologies in a fusion architecture system can be well met, whereby the flexibility is high, and a possibility of project implementation is provided for construction of the complex topologies in the fusion architecture system. The costs are low. Moreover, through many experiments, a highly feasible PCIe interconnection topology construction solution has been provided, which can meet construction requirements of complex topologies in different scenes while supporting a size standard definition of a server. It has high density, robustness, and flexibility, has sufficient PCIe expansion capability to connect uplink and downlink PCIe devices, and has high system robustness to maintain the stability of an IO switchboard system, which ensures IO data or PCIe signal exchange between many devices in an entire cabinet.

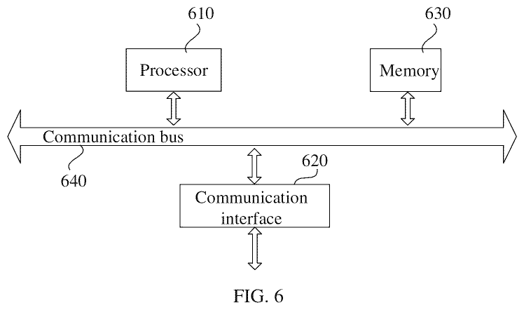

FIG. 6 shows a schematic diagram of an entity structure of an embodiment device. As shown in FIG. 6, the electronic device may include: a processor 610, a communications interface 620, a memory 630, and a communications bus 640. The processor 610, the communications interface 620, and the memory 630 achieve mutual communications through the communications bus 640. The processor 610 can invoke logic instructions in the memory 630 to perform a PCIe signal fusion management method. The method includes: receiving PCIe signals sent by PCIe devices; obtaining a target device type corresponding to the PCIe signal; determining at least one target interface corresponding to the target device type from all the connection interfaces of the current PCIe Switch chip based on the target device type, and determining a PCIe device connected to the target interface to be a target PCIe device; sending a state query instruction to the target PCIe device through the target interface; receiving a task processing state fed back by each target PCIe device, wherein the task processing state is fed back by the target PCIe device based on the state query instruction; and sending the PCIe signal to any target PCIe device with the task processing state being a free state.

In addition, the logic instructions in the memory 630 above can be implemented in the form of a software functional unit and sold or used as an independent product, and can be stored in a computer-readable storage medium. Based on such an understanding, the technical solutions of the present application essentially, or the part contributing to the related art, or some of the technical solutions may be implemented in the form of a software product. The computer software product is stored in a storage medium and includes several instructions for instructing a computer device (which may be a personal computer, a server, a network device, or the like) to execute all or some of the steps of the methods described in the various embodiments of the present application. The aforementioned storage media include: various media that can store program codes, such as a USB flash drive, a mobile hard disk drive, a Read-Only Memory (ROM), a Random Access Memory (RAM), a magnetic disc, and an optical disc.

In still another aspect, the present application further provides a non-transient computer-readable storage medium, having a computer program stored therein. When run by a processor, the computer program performs the PCIe signal fusion management method provided in the embodiments described above. The method includes: receiving PCIe signals sent by PCIe devices; obtaining a target device type corresponding to the PCIe signal; determining at least one target interface corresponding to the target device type from all the connection interfaces of the current PCIe Switch chip based on the target device type, and determining a PCIe device connected to the target interface to be a target PCIe device; sending a state query instruction to the target PCIe device through the target interface; receiving a task processing state fed back by each target PCIe device, wherein the task processing state is fed back by the target PCIe device based on the state query instruction; and sending the PCIe signal to any target PCIe device with the task processing state being a free state.

The apparatus embodiment described above is only schematic. The units described as separate parts may or may not be physically separate, and parts displayed as units may or may not be physical units, may be located in one position, or may be distributed on a plurality of network units. Some or all of the modules are selected according to actual needs to achieve the objective of the solution of this embodiment. Those of ordinary skill in the art can understand and implement the present application without creative work.

Through the description of the above implementations, those skilled in the art can clearly understand that the implementations can be implemented by relying on software and essential general-purpose hardware platforms, or certainly, by relying on hardware. Based on such an understanding, the technical solutions essentially, or the part contributing to the related technology, may be presented in the form of a software product. The computer software product can be stored in a computer-readable storage medium, such as a read only memory/random access memory (ROM/RAM), a magnetic disk, or a compact disc, including several instructions to enable a computer device (which may be a personal computer, a server, a network device, or the like) to perform methods described in the embodiments or some parts of the embodiments.

It should be finally noted that: The foregoing embodiments are merely intended to describe the technical solutions of the present application, but not for limiting the present application. Although the present application is described in detail with reference to the foregoing embodiments, persons of ordinary skill in the art should understand that they may still make modifications to the technical solutions described in the foregoing embodiments or make equivalent replacements to partial technical features thereof. However, these modifications or replacements do not make the essence of the corresponding technical solutions depart from the spirit and scope of the technical solutions of the various embodiments of the present application.

1. An input/output (I/O) expansion architecture, comprising:
at least one IO expansion unit, wherein the at least one IO expansion unit comprises an expansion baseboard, the expansion baseboard is provided with at least two peripheral component interface express (PCIe) Switch chips, a first preset quantity of internal connectors, and a second preset quantity of external connectors;
wherein one end of each of the internal connectors is connected to any one of the at least two PCIe Switch chips on the expansion baseboard, and a second end of the each of internal connectors is configured for interconnection between the at least two PCIe Switch chips; and one end of each of the external connectors is connected to any one of the at least two PCIe Switch chips on the expansion baseboard, and a second end of each of the external connectors is configured for being connected to a PCIe device, to achieve the interconnection between a plurality of PCIe devices.

2. An input/output (IO) switchboard, comprising:
an identity document (ID) management unit, a control module, and an IO extension architecture comprising:
at least one IO expansion unit, wherein the at least one IO expansion unit comprises an expansion baseboard, the expansion baseboard is provided with at least two peripheral component interface express (PCIe) Switch chips, a first preset quantity of internal connectors, and a second preset quantity of external connectors;
wherein one end of each of the internal connectors is connected to any one of the at least two PCIe Switch chips on the expansion baseboard, and a second end of each of the internal connectors is configured for interconnection between the at least two PCIe Switch chips; and one end of each of the external connectors is connected to any one of the at least two PCIe Switch chips on the expansion baseboard, and a second end of the external connectors is configured for being connected to a PCIe device, to achieve the interconnection between a plurality of PCIe devices;
wherein the ID management unit is configured to: acquire ID signals of all the internal connectors and all the external connectors in the IO expansion architecture, and transmit the ID signals to the control module; and
wherein the control module is configured to manage all of the at least two PCIe Switch chips in the IO expansion architecture based on all the ID signals.

3. The IO switchboard according to claim 2, wherein
each of the internal connectors and the external connectors is connected with an ID definition chip; the ID definition chip is configured to perform ID definition on a corresponding one of the internal connectors or the external connectors;
the ID management unit is specifically configured to send an ID query instruction to each of the ID definition chips through the corresponding one of the external connectors or the internal connectors;
the ID definition chip is further configured to receive the ID query instruction, and feedback, based on the ID query instruction, the ID signal to the corresponding one of the internal connectors or the external connectors;
in response to the corresponding one of the internal connectors or the external connectors receiving the ID signal, the ID signal is fed back to the ID management unit; and
the ID management unit is respectively connected to each of the external connectors, each of the internal connectors, and the control module.

4. The IO switchboard according to claim 2, wherein the control module comprises:
a baseboard management controller and at least one task management unit;
a multiplexer, configured to receive the ID signals transmitted by the ID management unit; and
a logic control unit, configured to: monitor operating states of the baseboard management controller and all of the at least one task management units; determine one of the baseboard management controller and all of the at least one task management units to be a target management unit based on the operating states, as well as task management priorities respectively corresponding to the baseboard management controller and the at least one task management units; generate a target management unit instruction based on the target management unit; and send the target management unit instruction to the multiplexer;
wherein the multiplexer is further configured to: determine the target management unit based on the target management unit instruction, and send the ID signals to the target management unit; and
wherein the baseboard management controller and each of the task management units are configured to: perform PCIe topology identification based on the ID signals in response to receiving the ID signals, to obtain a PCIe interconnection topology; and manage all of at least two PCIe Switch chips based on the PCIe interconnection topology;
wherein the ID management unit is connected to the multiplexer, and the multiplexer is respectively connected to the logic control unit, the baseboard management controller, and all of the task management units.

5. The IO switchboard according to claim 4, wherein the one-task management units comprises: a first task management unit and a second task management unit; and
wherein the logic control unit is specifically configured to:
determine the first task management unit to be the target management unit in response to determining that the first task management unit is in a normal operating state;
determine the second task management unit to be the target management unit in response to determining that the first task management unit is in an abnormal operating state and the second task management unit is in a normal operating state; and
determine the baseboard management controller to be the target management unit in response to determining that both the first task management unit and the second task management unit are in abnormal operating states and the baseboard management controller is in a normal operating state.

6. The IO switchboard according to claim 4, wherein the baseboard management controller and the task management units are specifically configured to send corresponding configuration information to each of the at least two PCIe Switch chips in response to identifying the PCIe interconnection topology;
wherein the configuration information comprises type information of all connection interfaces of a corresponding one of the at least two PCIe Switch chips;
wherein the connection interfaces comprise an interface configured to be connected to each of the internal connectors or each of the external connectors;
wherein the type information comprises: uplink interface information, downlink interface information, and internal interconnect interface information;
wherein the uplink interface information means that a corresponding connection interface is an uplink interface;
wherein the uplink interface is configured to transmit a PCIe signal to a PCIe device connected uplink;
wherein the downlink interface information means that the corresponding connection interface is a downlink interface;
wherein the downlink interface is configured to transmit the PCIe signal to a PCIe device connected downlink;
wherein the interconnect interface information means that the corresponding connection interface is an internal interconnect interface;
wherein the internal interconnect interface is configured to transmit the PCIe signal to remaining PCIe Switch chips of the at least two PCIe Switch chips interconnected with a current PCIe Switch chip of the at least two PCIe Switch chips;
wherein the PCIe device connected uplink is a host, and the PCIe device connected downlink is a graphics processing unit, a solid state drive, or a memory; and
wherein the current PCIe Switch chip is configured to configure all the connection interfaces of the current PCIe Switch chip based on the configuration information.

7. The IO switchboard according to claim 6, wherein each of the at least two PCIe Switch chips is configured to:
obtain a target device type corresponding to the PCIe signal in response to receiving the PCIe signal sent by the PCIe device;
determine at least one target interface corresponding to the target device type from all the connection interfaces of the current PCIe Switch chip based on the target device type, and determine a PCIe device connected to the at least one target interface to be a target PCIe device;
send a state query instruction to the target PCIe device through the at least one target interface; receive a task processing state fed back by the target PCIe device, wherein the task processing state is fed back by the target PCIe device based on the state query instruction; and
send the PCIe signal to any target PCIe device with the task processing state being a free state.

8. The IO switchboard according to claim 7, wherein each of the at least two PCIe Switch chips is specifically configured to: transmit the PCIe signal to a preset message queue in response to the task processing states fed back by the target PCIe device being an operating state; and transmit, based on the preset message queue in response to any target PCIe device being in the free state, the PCIe signal to the target PCIe device in the free state.

9. The IO switchboard according to claim 6, further comprising: a network management unit,
wherein the network management unit is respectively connected to the baseboard management controller, the task management units, and the at least one IO expansion unit, to achieve pairwise communication between the baseboard management controller, the at least one IO expansion unit, and all of the task management units.

10. The IO switchboard according to claim 2, further comprising: a heat dissipation unit, configured to perform heat dissipation on the IO switchboard.

11. The IO switchboard according to claim 4, further comprising a power rail unit, wherein an input end of the power rail unit is configured to be connected to a power supply unit; and an output terminal of the power rail unit is respectively connected to the at least one IO expansion unit, the ID management unit, the baseboard management controller, and the task management units, to supply power to the at least one IO expansion unit, the ID management unit, the baseboard management controller, and the task management units.

12. The IO switchboard according to claim 11, wherein the logic control unit is further configured to send a power on/off signal to the power rail unit, to control the power rail unit to start to supply or stop supplying power.

13. The IO switchboard according to claim 2, wherein the first preset quantity of the internal connectors are distributed on a first side of the expansion baseboard, and the second preset quantity of the external connectors are distributed on a second side of the expansion baseboard; and the first side and the second side are opposite sides.

14.-20. (canceled)

21. The IO switchboard according to claim 3, wherein the internal connectors and the external connectors each have different ID signals.

22. The IO switchboard according to claim 3, wherein the ID definition chips have a same inter-integrated circuit (I2C) address and are in an identical I2C channel.

23. The IO switchboard according to claim 4, wherein the ID signals are configured to be transmitted via any one of a Universal Serial Bus, an inter-integrated circuit (I2C) or a Universal Asynchronous Receiver/Transmitter.

24. The IO switchboard according to claim 4, wherein the baseboard management controller is further configured to monitor basic information of the IO switchboard, the basic information comprising temperature of the IO switchboard.

25. The IO switchboard according to claim 4, wherein the baseboard management controller communicates pairwise with all the task management units to achieve real-time data exchange and backup.

26. The IO switchboard according to claim 5, wherein the logic control unit is further configured to:
reboot the first task management unit in response to determining that the first task management unit is in the normal operating state; and
reboot the first task management unit and the second task management unit in response to determining that the first task management unit and the second task management unit are in the abnormal operating state.

27. The IO switchboard according to claim 9, wherein each of the at least two PCIe Switch chips is provided with a network interface for network connection.
